(19) United States
(12) Patent Application Publication
(10) Pub. No.: US 2012/0049954 A1
(43) Pub. Date: Mar. 1, 2012

(54) AMPLIFICATION CIRCUIT WITH LOW QUIESCENT CURRENT

(76) Inventors: Rui Wang, Chengdu (CN); Jinyan Lin, Hangzhou (CN); Huijie Zhao, Hangzhou (CN); Yunping Lang, Hangzhou (CN)

(21) Appl. No.: 13/218,376

(22) Filed: Aug. 25, 2011

(30) Foreign Application Priority Data
Aug. 26, 2010 (CN) 201010268563.0

(51) Int. Cl. H03G 1/00

(52) U.S. Cl. 330/127

(57) ABSTRACT

The embodiments of the present circuit and method disclose an amplification circuit including a voltage regulator, a negative charge pump and an amplifier. The output of the voltage regulator supplies the upper voltage supply of the amplifier and the output of the negative charge pump supplies the lower voltage supply of the amplifier. The voltage regulator and the negative charge pump make the power supply of the amplifier flexible, easy to be fabricated in semiconductor process.

### CROSS-REFERENCE TO RELATED APPLICATIONS

This application claims priority to and the benefit of Chinese patent application No. 201010268563.0, filed on Aug. 26, 2010, which is incorporated herein by reference in its entirety.

### TECHNICAL FIELD

This invention relates generally to electrical circuits, and more particularly but not exclusively to power amplifiers.

### BACKGROUND

A power amplifier takes an input signal and outputs a stronger signal whose amplitude may be proportional to the input signal. A power amplifier can provide a high quality, low total harmonic distortion (THD), amplified signal to output loads.

Typically, the amplifier is powered by a positive supply and a reference ground. But the problem is that there is a large quiescent current from the amplifier output stage to the reference ground through loads if the output is not biased to the reference ground. The quiescent current makes the amplifier efficiency lower and shortens the lifetime of the loads. Using a direct current (DC) decoupled capacitor can block the DC voltage flowing into the loads and thus reduce the quiescent current. For example, the magnitude of the capacitor can be several hundreds pico-farads. But it is hard to integrate the decoupled capacitor with the amplifier and the cost is increased.

Accordingly, an improved circuit is needed.

### SUMMARY

In one embodiment, the present circuit and method disclose an amplification circuit comprising a voltage regulator, a negative charge pump and an amplifier. The output of the voltage regulator may supply the upper voltage supply of the amplifier and the output of the negative charge pump may supply the lower voltage supply of the amplifier.

### BRIEF DESCRIPTION OF THE DRAWINGS

FIG. 1 illustrates a block diagram of a circuit using a low dropout regulator and a negative charge pump to generate the upper and lower power supplies for an amplifier in accordance with an embodiment of the present invention.

FIG. 2 illustrates a block diagram of an amplification circuit including two amplifiers, and the amplification circuit adopts a low dropout regulator to generate an upper power supply of the amplifiers and adopts a negative charge pump to generate a lower power supply of the amplifiers in accordance with an embodiment of the present invention.

FIG. 3 schematically illustrates one embodiment of a negative charge pump.

FIG. 4 graphically illustrates example control signals associated with the circuit of FIG. 3.

FIG. 5 schematically illustrates one embodiment of a low dropout regulator using a P-type device.

FIG. 6 schematically illustrates one embodiment of a low dropout regulator using an N-type device.

FIG. 7 schematically illustrates an amplification circuit having two low dropout regulators, one generates an upper power supply of an amplifier and the other generates a power supply of a negative charge pump in accordance with an embodiment of the present invention.

FIG. 8 schematically illustrates an amplification circuit comprising a switching circuit, an amplifier and a charge pump, where the switching circuit comprises a transistor string and has an output coupled to an upper power supply of the amplifier in accordance with an embodiment of the present invention.

The use of the same reference label in different drawings indicates the same or like components.

### DETAILED DESCRIPTION

In the present disclosure, numerous specific details are provided, such as examples of circuits, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

Throughout the specification and claims, the following terms take at least the meanings explicitly associated herein. The meanings specified below do not necessarily limit the terms, but merely provide illustrative examples for the terms. The term “pass device” may mean a silicon device having pass resistance controlled by signal at a control terminal. The term “switch” may mean a semiconductor device having “ON” and “OFF” states. The term “switch string” may mean more than one switch coupled in series. The term “transistor” may mean a filed effect transistor (FET) or a bipolar junction transistor (BJT). The terms “base”, “collector” and “emitter” may replace the terms “gate”, “drain” and “source” without departure from the spirit of the present invention. The term “transistor string” may mean at least more than one transistor coupled in series. The term “voltage drop” for a transistor may mean a drop in voltage between the collector and the emitter (i.e., V_{CE}) or a drop in voltage between the base and the emitter (i.e., V_{BE}).

FIG. 1 schematically shows one embodiment of the present invention. Circuit 100 as shown in FIG. 1 comprises a first regulator 101, a charge pump 102 and an amplifier 103. Regulator 101 has an input 11 and an output 12 which is coupled to the upper power supply input of amplifier 103 at node SP. The output 12 of regulator 101 is regulated at a predetermined voltage. In one embodiment, regulator 101 is a low dropout regulator (LDO) which generates a positive voltage coupled to the upper power supply input of amplifier 103 at node SP. Charge pump 102 has an input 13 and an output 14 which is coupled to the lower power supply input of amplifier 103 at node SN. In one embodiment, charge pump 102 is a negative charge pump (NCP) which generates a negative voltage coupled to the lower power supply input of amplifier 103 at node SN. The input 13 of charge pump 102 may be coupled to input 11 or output 12 of regulator 101. Amplifier 103 has an upper power supply input at node SP, a lower power supply input at node SN, an input 1031 and an output 1032. The absolute value of the lower power supply voltage at node SN may be less than the absolute value of the upper power supply voltage at node SP. The input 1031 of amplifier 103 may be single ended or differential, but only single ended input for amplifier 103 is shown in FIG. 1 as an example. The signal V_{OUT} at output 1032 of amplifier 103 may have the maximum swing range between the SP node voltage and the SN node voltage. It is easy to bias voltage at output 1032 of amplifier 103 to reference ground when the upper power supply input is supplied with a positive voltage and the lower power supply input is supplied with a negative voltage. Circuit 100 is easy to be fabricated by semiconductor process with the flexible power supply required by the upper and lower power supply inputs of the amplifier.

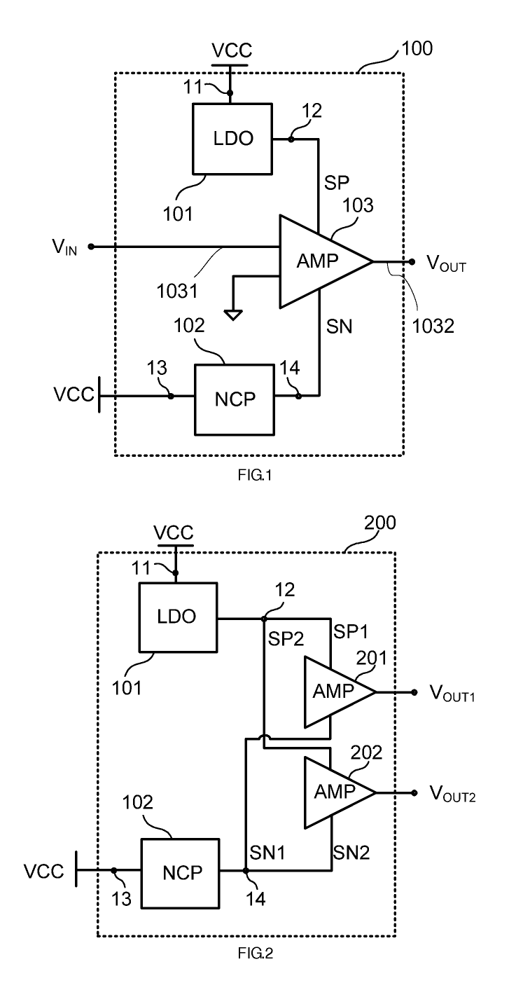

Circuit 100 may comprise more amplifiers and all the amplifiers may share the same voltage at the upper power supply inputs or share the same voltage at the lower power supply inputs. The upper power supply input of each amplifier may be coupled to output 12 of regulator 101 and the lower power supply input of each amplifier may be coupled to output 14 of charge pump 102. FIG. 2 schematically shows a circuit 200 comprising two amplifiers 201 and 202 in accordance with an embodiment of the present invention. In one embodiment, the output 12 of regulator 101 is coupled to both the upper power supply input of amplifier 201 at node SP1 and the upper power supply input of amplifier 202 at node SP2. In one embodiment, the output 14 of charge pump 102 is coupled to both the lower power supply input of amplifier 201 at node SN1 and the lower power supply input of amplifier 202 at node SN2. In one embodiment, the output signal V_{OUT1} of amplifier 201 is different from the output signal V_{OUT2} of amplifier 202.

In one embodiment, the input 13 of charge pump 102 is coupled to input 11 of regulator 101 as illustrated in FIG. 1 and FIG. 2. In another embodiment, the input 13 of charge pump 102 is coupled to output 12 of regulator 101. Yet in another embodiment, the input 13 of charge pump 102 is coupled to other voltage source. The low dropout regulator 101 may be substituted by other type of voltage regulator which comprises an input and an output.

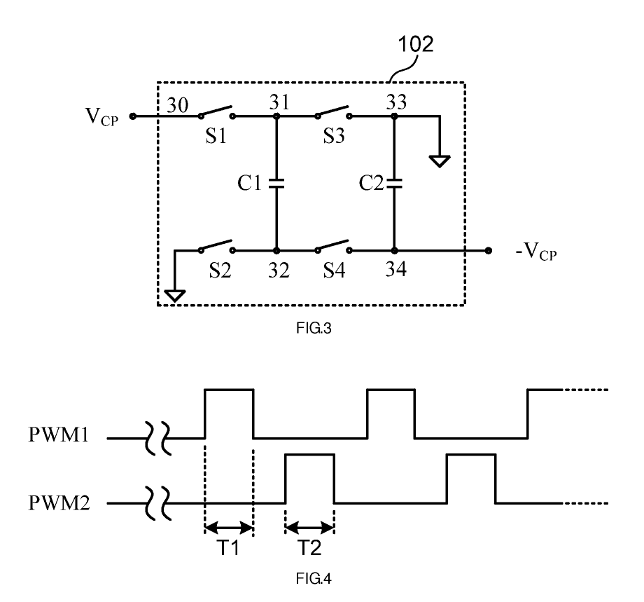

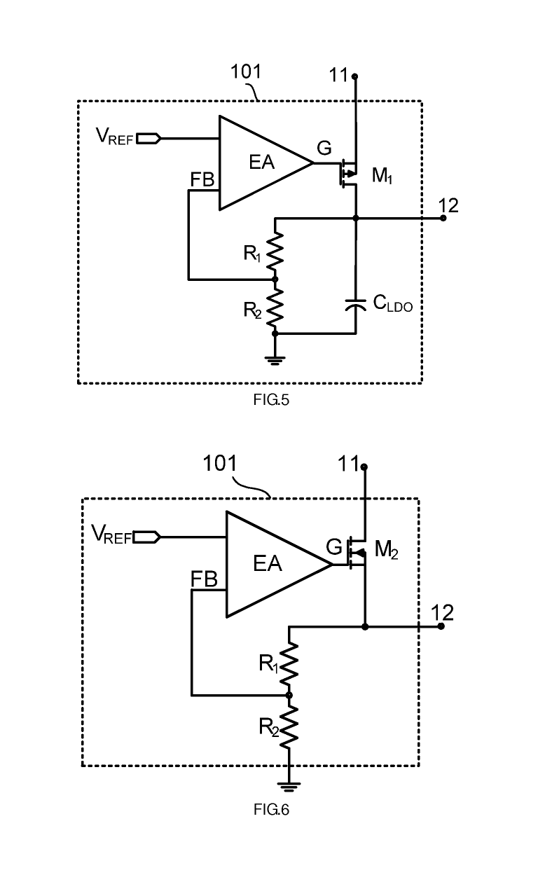

A charge pump is one type of DC to DC converter that uses capacitors as energy storage elements to create a voltage power source. Charge pump uses some switching devices to control the connection of voltages to the capacitors. FIG. 3 schematically shows one embodiment of charge pump 102 comprising an input, an output, some capacitors and some switch devices. A first terminal of switch 51 is coupled to the input of charge pump 102 at node 30 and a second terminal of switch 51 is coupled to a first terminal of capacitor C1 at node 31. A first terminal of switch S2 is coupled to reference ground and a second terminal of switch S2 is coupled to a second terminal of capacitor C1 at node 32. A first terminal of switch S3 is coupled to the first terminal of capacitor C1 at node 31 and a second terminal of switch S3 is coupled to both the reference ground and a first terminal of capacitor C2. A second terminal of capacitor C2 provides a negative output voltage of charge pump 102 at node 34. A first terminal of switch S4 is coupled to the second terminal of capacitor C1 at node 32 and a second terminal of switch S4 is coupled to the second terminal of capacitor C2 at node 34. FIG. 4 shows the control signals for the switches S1, S2, S3 and S4 as an embodiment. PWM1 is the control signal for both switch S1 and switch S2, PWM2 is the control signal for both switch S3 and switch S4. PWM1 actives switch S1 and switch S2 during the time period T1 when PWM1 is logic high, PWM2 actives switch S3 and switch S4 during the time period T2 when PWM2 is logic high. PWM1 and PWM2 are non-overlapping clock signals. In one embodiment, a charge proportional to voltage V_{CP} at node 30 is stored to capacitor C1 when both switch S1 and switch S2 are active, and the stored charge on capacitor C1 is transferred to capacitor C2 when both switch S3 and switch S4 are active. As a result, the voltage on the second terminal of capacitor C2 at node 34 is −V_{CP} with respect to reference ground.

FIG. 5 schematically shows one embodiment of low dropout regulator 101 comprising a P-type pass device M1, an error amplifier EA and a feedback circuit. The Input 11 supplies voltage through the pass device M1 to output 12. The pass device M1 is a P-type transistor. In one embodiment, the pass device M1 is a P channel metal oxide semiconductor FET (MOSFET) as shown in FIG. 5. In another embodiment, the pass device M1 is a PNP transistor. The error amplifier EA comprising two inputs terminal and one output terminal. In one embodiment, the voltage at output 12 is feed back to one input of the error amplifier EA at node FB and a predetermined voltage V_{REF} is coupled to the other input of the error amplifier EA. The output of the error amplifier EA is coupled to the gate of pass device M1. In one embodiment, the feedback circuit comprises resistors R1 and R2 connected in serial. One end of R1 is coupled to output 12, and the other end of R1 is coupled to node FB. One end of R2 is couple to node FB and the other end of R2 is coupled to the reference ground. Thus the voltage at output 12 is divided by resistors R1 and R2 and is proportional to the voltage at feedback node FB. The error amplifier EA compares the voltage at node FB with the predetermined voltage V_{REF} and adjusts its output to force the voltage at node FB equaling V_{REF}. The error amplifier keeps the voltage at node FB equaling V_{REF} ideally and the voltage at output 12 is regulated to V_{REF}·(R1+R2)/R2. In another embodiment, the voltage at output 12 is regulated to V_{REF} when the output 12 is coupled to node FB directly. In one embodiment, a capacitor is coupled between output 12 of low dropout regulator 101 and the reference ground.

FIG. 6 schematically shows one embodiment of low dropout regulator 101 comprising an N-type pass device M2. The input 11 supplies voltage through the pass device M2 to output 12. The pass device M2 may be an N-type transistor, for example, an N-channel MOSFET. In another embodiment, the pass device M2 is an NPN BJT transistor.

In one embodiment, there is a second regulator having an input and an output and the output of the second regulator is coupled to the input of the charge pump. The noise generated by the upper power supply of the amplifier may be reduced when the input of charge pump is not coupled to the input or the output of the first regulator whose output is coupled to the upper power supply input of the amplifier.

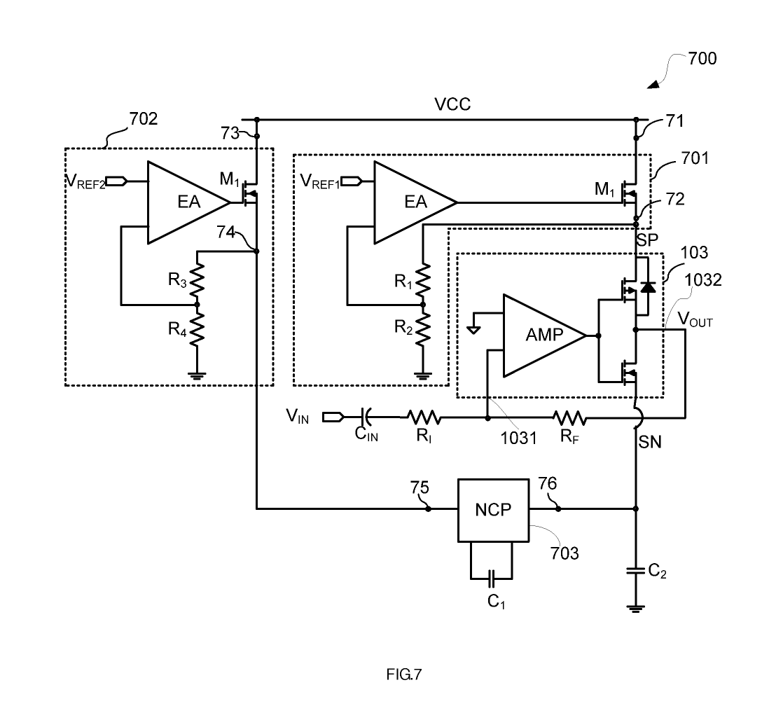

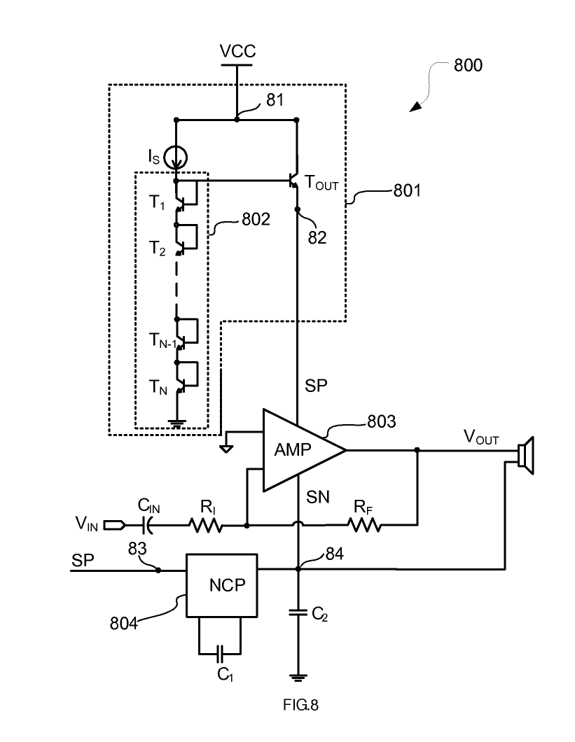

FIG. 7 shows circuit 700 as one embodiment of the present invention. Circuit 700 comprises two regulators 701 and 702, an amplifier 103 and a charge pump 703. Regulator 701 comprises an input 71 and an output 72. The output 72 of regulator 701 is coupled to the upper power supply input of amplifier 103 at node SP. Regulator 702 comprises an input 73 and an output 74. The output 74 of regulator 702 is coupled to an input 75 of charge pump 703. In one embodiment, external voltage labeled as VCC is coupled to input 71 of regulator 701 and input 73 of regulator 702. In other embodiments, the input 71 and the input 73 may come from different external voltage source. The output 76 of negative charge pump 703 is coupled to the lower power supply input of amplifier 103 at node SN. Amplifier 103 comprises an upper power supply coupled to output 72 of regulator 701, a lower power supply coupled to output 76 of charge pump 703, an input 1031 and an output 1032. In one embodiment, C_{IN} and R_{I} are used before input terminal 1031 of amplifier 103 for filtering the input signal V_{IN}. R_{F} may be used as a feedback resistor to set the ratio between output signal V_{OUT} and input signal V_{IN}.

In one embodiment, the regulator for supplying the upper power supply input of amplifier 103 comprises a switch string and the output of the regulator is clamped by the voltage drop of the switch string. The switch string may be diode string or transistor string. The regulator comprises an output circuit having a control terminal, a first terminal and a second terminal. The control terminal is coupled to the switch string, the first terminal is coupled to the input of the regulator and the second terminal is served as the output of the regulator. In one embodiment, the output circuit is a transistor. The output voltage may be clamped by the switch string when the input voltage of the regulator is larger than the voltage drop of the switch string.

FIG. 8 schematically shows a circuit 800 comprising a transistor string according to an embodiment of the present invention. Circuit 800 comprises a switching circuit 801, an amplifier 803 and a charge pump 804. As shown in FIG. 8, switching circuit 801 has an input 81 and an output 82. The output 82 is coupled to the upper power supply input of amplifier 803 at node SP. In one embodiment, switching circuit 801 receives voltage VCC at input 81 and then outputs a positive voltage at output 82 which is coupled to the upper power supply input at node SP. Charge pump 804 has an input 83 and an output 84 which is coupled to the lower power supply input of amplifier 803 at node SN. In one embodiment, the input 83 of charge pump 804 is coupled to output 82 of switching circuit 801.

In one embodiment, switching circuit 801 comprises a transistor string 802, a current source I_{S}, and a transistor Tₒᵤᵣ. In FIG. 8, the transistor in transistor string 802 or the transistor T_{OUT} is an NPN bipolar junction transistor in accordance with an embodiment. The transistor string 802 comprises several transistors T₁, T₂, T₃ . . . T_{N} connected in series, and N is the quantity of transistors in series, for example N=5 means there are 5 transistors in series. The base is connected to the collector for each transistor in transistor string 802. The collector of T₂ is connected to the emitter of T₁; the collector of T₃ is connected to the emitter of T₂, and so on. The collector of T₁ is coupled to input 81 through the current source I_{S}. The current source I_{S} has a first terminal connected to input 81 and a second terminal connected to the collector of T1. The emitter of T_{N} is connected to reference ground. The collector and base of T₁ is connected to the base of T_{OUT}. The collector of T_{OUT} is connected to input 81 and the emitter of T_{OUT} is served as the output 82 of switching circuit 801. Ideally each transistor in transistor string 802 and T_{OUT} has the same voltage drop V_{BE} when it is in ON state. The input 81 receives a voltage VCC as shown in FIG. 8. The transistors in transistor string 802 would be turned ON when VCC>N·V_{BE}, the base voltage of T_{OUT} is clamped to N·V_{BE}, and then the voltage at output 82 coupled to node SP equals (N−1)·V_{BE}. On contrast, the transistors in 802 would be turned OFF when VCC≦N·V_{BE} and the voltage at output 82 equals to VCC−V_{CE}. V_{CE} is the voltage drop between the collector and the emitter of T_{OUT}.

In other embodiments, transistor string 802 may be substituted by a diode string which comprises a plurality of diodes connected in series.

According to the embodiment in FIG. 8, the upper power supply input at node SP of the amplifier is not directly connected to external voltage VCC at input 81 but clamped by the voltage drop of the transistor string. The voltage V_{SP} at node SP is clamped to (N−1)·V_{BE} in one embodiment. V_{SP}=(N−1)·V_{BE}, when VCC is larger than N·V_{BE}. And V_{SP}=VCC−V_{CE}, when VCC is less than N·V_{BE}. In the embodiment of FIG. 8, the voltage stress across the amplifier is adaptively reduced by using a simple switching circuit. Switching circuit 801 does not need a feedback control loop and is easy to be integrated.

The above description and discussion about specific embodiments of the present technology is for purposes of illustration. However, one with ordinary skill in the relevant art should know that the invention is not limited by the specific examples disclosed herein. Variations and modifications can be made on the apparatus, methods and technical design described above. Accordingly, the invention should be viewed as limited solely by the scope and spirit of the appended claims.

What is claimed is:

1. A circuit, comprising:
a first regulator comprising a first input and a first output, the first output is regulated at a predetermined voltage;
a charge pump comprising a second input and a second output; and
an amplifier comprising an upper power supply input coupled to the first output, and a lower power supply input coupled to the second output.

2. The circuit of claim 1 wherein the first output is configured to output a positive voltage and the second output is configured to output a negative voltage.

3. The circuit of claim 1 further comprising multiple amplifiers, each amplifier comprising an upper power supply input coupled to the first output and a lower power supply input coupled to the second output.

4. The circuit of claim 1 wherein the second input is coupled to either:
(a) the first input; or
(b) the first output.

5. The circuit of claim 1 wherein the first regulator is a low dropout regulator.

6. The circuit of claim 5 wherein the low dropout regulator comprises a P-type transistor and a capacitor, and wherein the capacitor is coupled between the first output and a reference ground.

7. The circuit of claim 1 further comprising a second regulator having an input and an output, wherein the output of the second regulator is coupled to the second input.

8. The circuit of claim 1 wherein the first regulator comprises a switch string and the first output is clamped by the voltage drop of the switch string during a period of time.

9. The circuit of claim 8 wherein the switch string comprises either:
(a) a diode string; or
(b) a transistor string.

10. The circuit of claim 1 wherein the first regulator comprising:
a current source, comprising an input coupled to the first input;
a transistor string, coupled in series between the current source and a reference ground; and
a transistor comprising a control terminal, a first terminal and a second terminal, wherein the control terminal is coupled to the current source and the transistor string, the first terminal is coupled to the first input and the second terminal is coupled to the first output.

11. The circuit of claim 10, wherein the transistors are bipolar junction transistors each comprising a base, a collector and an emitter; wherein the transistor string comprises a plurality of transistors connected in serial with the current source and wherein:
the base of each transistor is coupled to its collector;
the collector of the first transistor is coupled to the current source;
the collector of each other transistors is coupled to the emitter of the corresponding antecedent transistor; and
the emitter of the last transistor is coupled to the reference ground.

12. A circuit, comprising:
a switching circuit, comprising a switch string, wherein the switching circuit has a first input and a first output, and wherein the first output is configured to output a positive voltage;
a charge pump, having a second input and a second output, wherein the second output is configured to output a negative voltage; and
an amplifier, having an upper power supply input coupled to the first output, and a lower power supply input coupled to the second output.

13. The circuit of claim 12 wherein the first output is configured to be clamped by the voltage drop of the switch string during a period of time.

14. The circuit of claim 12 wherein the switching circuit further comprises:
a current source; and
an output transistor comprising a control terminal, a first terminal and a second terminal;
wherein the switch string comprises a plurality of switches connected in serial with the current source at a common node, and wherein the control terminal of the transistor is coupled to the common node, the first terminal is coupled to the first input and wherein the second terminal is coupled to the first output.

15. The circuit of claim 14, wherein each switch comprises a second control terminal, a third terminal and a fourth terminal, and wherein:
the second control terminal is coupled to its third terminal;
the third terminal of the first switch is coupled to the current source;
the third terminal of each the other switches is coupled to the fourth terminal of the corresponding precedent switch;
and the fourth terminal of the last switch is coupled to a reference ground.

16. The circuit of claim 14, wherein the transistor is a bipolar junction transistor.

17. A method of supplying power to an amplifier, the method comprising:
regulating a first voltage into a first output voltage in positive value;
charge pumping a second input and providing a second output voltage in negative value; and
using the first output supplying the amplifier at the upper power supply input and using the second output supplying the amplifier at the lower power supply input.

18. The method of claim 17 wherein the second input is coupled to either:
(a) the first input; or
(b) the first output.

19. The method of claim 17 wherein the first output is clamped at the voltage drop of a switch string.

20. The method of claim 17 wherein the second input is supplied by an output of another voltage converter.
